(19) United States
(12) Patent Application Publication
(10) Pub. No.: US 2002/0168538 A1
(43) Pub. Date: Nov. 14, 2002

(54) Wire-bonding alloy composites

(76) Inventor: Timothy W. Ellis, Doylestown, PA (US)

Correspondence Address: Synnestvedt & Lechner LLP, 2600 Aramark Tower, 1101 Market Street, Philadelphia, PA, 19107-2950, US

(21) Appl. No.: 10/128,072

(22) Filed: Apr. 23, 2002

Related U.S. Application Data
(63) Continuation of application No. 09/396,685, filed on Sep. 14, 1999.
(60) Provisional application No. 60/100,272, filed on Sep. 14, 1998.

(51) Int. Cl. B22F 3/26; H01L 23/48

(52) U.S. Cl. 428/567; 428/576; 257/784

(57) ABSTRACT

A metal alloy composite comprising a phase of a highly-conductive base metal in the from of a matrix and a phase of another metal positioned within the matrix, the base metal being present in a major amount and the other metal being present in a minor amount, the metal alloy composite being capable of being formed into a very thin wire for use in a semiconductor application which includes a terminal assembly comprising an electrically conductive terminal in conductive contact with a conductive member and another electrically conductive terminal in conductive contact with a semiconductor, said terminals being joined by said alloy composite wire, examples of the base metal being gold, copper, and aluminum.

### CROSS-REFERENCE TO RELATED APPLICATION

This application is based on and claims the benefit of prior filed co-pending provisional application No. 60/100,272, filed Sep. 14, 1999.

### FIELD OF THE INVENTION

The present invention relates to a highly-conductive alloy composite. More particularly, the present invention relates to a highly-conductive alloy composite which is capable of being formed into a small-diameter wire that has a combination of highly desired properties.

The present invention will be described initially in connection with the use of gold wire and with the use of copper wire in forming electrical connections, for example, in applications involving the coupling of electrical contact pads of a semiconductor die to the pins of a lead frame. It should be understood, however, that aspects of the present invention have broader applicability, as described below.

Gold and copper are metals that are used widely as electrical wire connectors, for example, in semiconductor applications and other applications where high conductivity, strength, and stability are required. Gold and copper are metals of choice for such applications because they have a combination of desired properties. For example, gold is highly conductive (less than about 3 micro ohm-cm), malleable, and stable. Gold resists being oxidized and is otherwise highly corrosion-resistant. Copper is also highly conductive and has desired strength and elastic modulus properties.

A typical semiconductor application involves the use of a conductive wire which joins conductive terminals, for example, a conductive terminal positioned on the semiconductor and a conductive terminal positioned on an outside lead member, for example, a carrier, package or other substrate. Typically, the wire used in such applications is very thin, for example, about 20 to about 35 microns. The mechanical strength of gold is, however, lower than what it should be for effective use in such applications. Shortcomings of copper for use in such applications are relatively low corrosion-resistance, for example, its tendency to oxidize.

It is known to alloy gold and to alloy copper with one or more other metals to improve their properties to make them more suitable for use in semiconductors and other applications where high conductivity, strength, and stability are required.

The present invention relates to a highly-conductive alloy which comprises a major amount of a highly conductive metal and which has a combination of desired properties, including improved strength and other desired properties which are needed for effective use of the alloy in semiconductor and other electrical applications.

### REPORTED DEVELOPMENTS

U.S. Pat. No. 4,775,512 discloses a wire-bonding gold line which is characterized as having excellent mechanical strength and low electrical resistance. The gold line is a gold alloy which includes germanium or a mixture of germanium and beryllium as alloying constituents.

It is known also to use other metals as alloying constituents to improve the strength of gold wire. Examples of such metals are calcium, metals of the lanthanide series, for example, lanthanum and neodymium, and Transition elements, for example, copper, silver, titanium, and platinum. Such metals are microalloyed typically in relatively small amounts (for example, <0.1 volume %).

U.S. Pat. No. 4,676,827 discloses very fine copper alloy wires for use in the bonding of semiconductor chips. The copper alloy comprises high-purity copper and (A) at least one rare earth element or (B) at least one element of magnesium, calcium, titanium, zirconium, hafnium, lithium, sodium, potassium, rubidium, or cesium or a mixture of the elements of (A) and (B). This patent discloses also a copper alloy wire comprising an element of aforementioned (B) and yttrium. In addition, this patent discloses a copper alloy wire comprising sulfur, selenium or tellurium. Still another copper alloy wire disclosed in this patent comprises yttrium and a rare earth element.

The nature of the aforementioned “alloying” metals and the amounts used are such that the gold or copper, that is, the base metal and alloying metal are substantially miscible in each other, that is, the alloying metal is dissolved substantially completely in the molten base metal solution from which the base metal alloy is formed. Thus, the resulting base metal alloy comprises a solid solution of base metal and the alloying metal.

Although such base metal alloy solid “solutions” are used widely, there are problems associated with their use. For example, the conductivity of the base metal alloy is typically lower than the conductivity of the pure base metal. In the formation of a long interconnection for semiconductor devices (for example, about 250 mils), it is desired that the wire have little or no sway in order to avoid short-circuiting caused by contact with an adjacent wire. It is known that the tendency of a wire to sway can be reduced by increasing the elastic modulus (stiffness) of the material comprising the wire. Another problem associated with the use of the aforementioned type of gold alloys is that it is difficult, if not impossible, to form extremely thin wires that have a satisfactory elastic modulus.

The present invention relates to a highly-conductive metal alloy wire which, relative to prior art wires, has improved strength, elastic modulus, and other desired properties that are expected to be possessed by wires that are used in semiconductor applications and to semiconductor applications including the use of such wires.

### SUMMARY OF THE INVENTION

In accordance with the present invention, there is provided a metal alloy composite comprising a phase of a highly-conductive base metal in the form of a matrix and a phase of another metal positioned within the matrix, the base metal being present in a major amount and the other metal being present in a minor amount, the metal alloy composite being capable of being formed into very thin wires for use in semiconductor applications. The “other” metal can be present in the base metal matrix in various forms, for example, in the form of dendrites. It is expected that the metal alloy composite of the present invention will be used widely in the form of a wire, particularly for use in semiconductor applications. In preferred form, the wire will include the “other” metal (also referred to herein as “the alloying constituent”) in an elongated form, for example, parallel, axially aligned fibers.

In accordance with another aspect of the present invention, there is provided a terminal assembly comprising an electrically conductive terminal in conductive contact with a conductive member and another electrically conductive terminal in conductive contact with a semiconductor, said terminals being joined by a wire comprising a metal alloy composite comprising a phase of highly conductive base metal in the form of a matrix and a phase of another metal positioned within the matrix, the base metal being present in a major amount and the other metal being present in a minor amount.

In preferred form, the wire for use in such an assembly comprises a gold alloy or a copper alloy and has a diameter of no greater than about 30 microns, an ultimate tensile strength of at least about 300 Mpa, and a tensile elongation of at least about 1%.

Still another aspect of the present invention is the provision of a metal alloy composite comprising a phase of gold in the form of a matrix and a phase of another metal positioned within the matrix, the gold being present in a major amount and the other metal being present in a minor amount. The “other” metal can be present in the gold matrix in various forms, for example, in the form of dendrites.

Preferred alloying constituents for use in the gold alloy of the present invention include iridium, rhodium, molybdenum, a mixture of iron and vanadium, a mixture of iron and molybdenum, a mixture of nickel and niobium, and a mixture of iron and silicon.

Another aspect of the present invention is the provision of a process for preparing a gold alloy composite comprising:

(A) forming a mixture containing a major amount of molten gold and a minor amount of another metal, the other metal being molten and immiscible with the molten gold or being solid and insoluble in the molten gold; and

(B) cooling the mixture under conditions which are effective in forming a solid gold alloy composite comprising a phase of gold in the form of a matrix and a phase of the other metal positioned in the matrix.

In preferred form, the aforementioned mixture is formed by crucible melting or consumable arc melting and the mixture is cooled under conditions which include chill casting or mold casting, for example, directional casting, continuous casting, and melt spinning.

An additional aspect of the present invention encompasses a process for preparing a gold alloy wire comprising:

(A) providing a solid composition comprising a phase of gold in the form of a matrix and a phase of another metal positioned within the matrix, the gold being present in the composition in a major amount and the other metal in a minor amount; and

(B) subjecting the composition to deformation processing under conditions which shape the composition into the form of a wire which includes a plurality of parallel axially aligned fibers or elongated particles of the other metal. In preferred form, the deformation processing used in forming the wire of the present invention involves extrusion, swaging, and wire drawing operations.

The gold alloy of the present development is distinguishable from conventional gold alloys in which the improved strength of the alloy is achieved through the formation of a solid solution or a precipitate-hardening mechanism. The gold alloy of this invention is based on the use of an alloying constituent which is immiscible (insoluble) in molten (liquid) gold at the melting point of the gold at atmospheric pressure. In contrast, the alloying constituent of a conventional gold alloy is miscible (soluble) in molten (liquid) gold at its melting point. Thus, gold alloys of the prior art are typically homogeneous in form and consist of one phase in that they are solid solutions of the alloying constituent dissolved in gold. In contrast, embodiments of alloys of the present invention can be viewed as comprising two phases in which the alloying constituent is dispersed or otherwise distributed in a continuous phase of gold.

### DETAILED DESCRIPTION OF THE INVENTION

The highly conductive base metal (for example, gold or copper) constituent for use in the alloy composite of the present invention should be substantially pure. The purity of the base metal will depend on the particular application in which the alloy composite is used. It is believed that a base metal purity of at least about 98% will be satisfactory for most applications. It is recommended that a base metal purity of at least about 99.9% be used for applications involving electronic and semiconductor assembly.

The term “highly-conductive base metal” means a metal whose electrical conductance is less than about 3 micro ohm-cm. The use of gold is highly preferred because it has a combination of particularly good properties. Copper and aluminum are preferred base metals, with copper being the metal of choice for a wider variety of applications than aluminum. Examples of other highly conductive base metals are nickel, palladium, and silver which may find use in selected applications.

The alloying constituent for use in the alloy composite of the present invention can be any metal which is: (A) immiscible with the base metal in a molten mixture of the base metal and the alloying constituent; (B) capable of existing in a separate phase in a solid form of the mixture; and (C) imparts desired properties to the composite. It should be understood that the alloying constituent may be a metal which is partially soluble (miscible) with the molten base metal, in which case, the alloying constituent is used in an amount in excess of the amount that is capable of being dissolved by the base metal. For example, chromium is partially soluble in solid copper. The solubility of the alloying constituent at equilibrium (25° C.) is preferably no greater than about 1 wt. % in the base metal and is preferably no greater than about 0.1 wt. %. The invention includes within its scope embodiments in which the base metal matrix comprises a phase of a solid solution in which a portion of the alloying constituent is dissolved in the base metal and a phase which includes the portion of the alloying constituent which is not dissolved in the solid solution.

It should be understood also that the alloying constituent can be a metal which is in a solid form (immiscible) in the molten base metal, for example, dispersed therein in the form of solid insoluble particles.

The alloying constituent is a material which imparts desired properties to the base metal alloy composite of the present invention. Accordingly, the selection of the alloying constituent will depend on the base metal that comprises the alloy and the properties thereof to be improved. Examples of such properties include improved strength, elastic modulus and minimal effect on electrical properties, for example, conductivity, and inductance.

With respect to the use of gold as the base metal, selection of the alloying constituent is based on the gold property to be improved. Speaking generally, a metal which has a “better-than-gold” property can be used. For example, metals that have higher strength than gold can be used to improve the strength of the composite. Similarly, to improve the elastic modulus, a metal that has a higher elastic modulus than gold can be used. Two or more alloying constituents which are immiscible in the molten gold mixture can be used to impart desired properties to the composite.

With respect to the use of copper as the base metal, a metal which has a “better-than-copper” property can be used. For example, metals that have a higher elastic modulus, higher mechanical strength, or better corrosion-resistance than copper can be used to improve the properties of the alloy composite. Two or more alloying constituents which are immiscible in the molten copper mixture can be used to impart desired properties to the composite.

There may be included also in the highly-conductive base metal alloy composite a metal which is miscible (soluble) in the molten base metal mixture and which, as the mixture solidifies, forms a solid solution with the base metal in the composite. The “miscible” alloying constituent can be selected so as to impart to the composite desired properties. A base metal alloy composite which includes a “miscible” alloying constituent comprises a matrix of a solid solution of the base metal and the “miscible” alloying constituent and a phase of the “immiscible” alloying constituent positioned within the matrix.

Examples of “miscible” alloying elemental metals which can be used in a gold alloy composite are niobium and tantalum. Examples of “miscible” alloying elemental metals that can be used in a copper alloy composite are cobalt and iron.

The alloying constituent is included in the composite in an amount sufficient to impart to the composite the desired properties. The minimum amount will vary, depending on the metal used. Generally speaking, small amounts can be used. It is believed that, for most applications, observable improvements in properties will be achieved by use of about 2 volume percent of the alloying constituent. (Unless indicated otherwise, the proportion of alloying constituent comprising the alloy is stated in volume percent (vol. %) based on the total volume of the composite.) The maximum amount of alloying constituent used is governed by the maximum mechanical properties versus electrical performance requirements.

It is recommended that the alloying constituent comprise about 3 to about 40 vol. % of the composite and preferably about 7 to about 15 vol. %. The optional “miscible” alloying constituent can comprise about 3 to about 40 vol. % of the composite and preferably about 7 to about 15 vol. %.

Preferred “immiscible” alloying constituents for use in the gold alloy composites of the present invention are iridium and molybdenum. Particularly, preferred gold alloy composites of the present invention include 90% gold and the following “immiscible” alloying constituent(s) in the proportion indicated.

10% iridium

10% rhodium

7.5% molybdenum

10% molybdenum

8.0% iron and 2% vanadium

8.0% niobium and 2% molybdenum

9.5% iron and 0.5% molybdenum

9.5% nickel and 0.5% niobium

9.5% iron and 0.5% silicon

Examples of “immiscible” alloying constituents for use in copper alloy composites of the present invention are chromium, molybdenum, vanadium, niobium, tantalum, and iridium, with niobium being preferred. Particularly, preferred copper alloy composites of the present invention include the “immiscible” alloying constituents listed below in the proportions indicated, with copper comprising the balance of the composites.

3% niobium

5% niobium

10% niobium

3% chromium

5% chromium

10% chromium

5% tantalum

5% vanadium

Composites of the present invention are capable of being formed into wire having a combination of desired properties, for example, a diameter of no greater than about 50 microns, a strength of at least about 300 Mpa, and a tensile elongation of at least about 1%. Preferred wire of the present invention has a diameter of about 10 to about 40 microns, a strength of about 300 to about 1000 Mpa, and a tensile elongation of about 1 to about 15%. Particularly preferred wire has a diameter of about 15 to about 30 microns, a strength of about 500 to about 1000 Mpa and a tensile elongation of about 2 to about 8.

The highly-conductive base metal alloy composite of the present invention can be prepared by any suitable method. The method of choice will depend on the application in which the composite is to be used. Speaking generally, the mixture of constituents comprising the composite can be formed initially into an ingot. Thereafter, the ingot can be shaped or otherwise transformed into the desired form.

Typically, a powder of the alloying constituent is combined with the highly-conductive base metal. The powder can be formed by melting an ingot of the metal alloying constituent and then atomizing the liquid, for example, by use of argon gas, into powders having a suitable size, for example, about 0.5 to about 50 microns.

Preferably, the ingot comprises a substantially uniform distribution of alloying constituent in the base metal matrix in the form of small particles, for example, about 0.1 to about 10 microns. Exemplary ways of preparing ingots of the alloy composite include the use of conventional melt processing and of powder metallurgy. Melt processing includes crucible melting or consumable arc melting or non-consumable arc welding or plasma/electron-beam melting. An important advantage of using melt processing is the ability to disperse uniformly the alloying constituent in the base metal matrix. Powder metallurgy consists of mixing powdered base metal and the powdered alloying constituent to form a mixture which is subjected to pressing, sintering, or hot isostatic pressing. An important advantage of using powder metallurgy is the ability to use a highly insoluble alloying constituent in forming the composite.

The alloying constituent can be present in the base metal matrix in various forms, depending on the way in which the composite is formed. For example, the alloying constituent can be present as solid particles which are dispersed in the base metal matrix or as second phase dendrites or as a meta-stable supersaturated solid solution.

The preferred means for forming wire comprising the alloy composite of the present invention involves the use of deformation processing (cold-drawing) which is effective in transforming the alloying constituent in the base metal matrix into elongated fibers, elongated ribbons, or particles. Deformation processing is known for use in forming alloys of other metals, for example, as described in American Society of Metals Handbook. This technique of wire formation generally involves extrusion or swaging followed by wire drawing. The stress imposed upon the composite needs to be sufficient to deform the particles of alloying constituents into an elongated fiber or ribbon. For this purpose, the amount of stress should be in excess of the yield or flow stress of the alloying constituent. The amount of stress needed will depend on various factors, including, for example, the particular alloying constituent used, the particle size of the constituents, and the amount of impurities present.

In certain embodiments of the invention, it has been observed that, during deformation, spheroidal particles of the alloying constituents which are dispersed in the base metal matrix are flattened and elongated to a ribbon-like morphology. The ribbons can have a thickness approaching that of nanophase materials. Further deformation forces the ribbons to fold upon themselves to accommodate the strain of the surrounding base metal matrix. It has been determined that some of the particles can remain undeformed, for example, about 1 vol. %. The presence of higher amounts of undeformed particles can lead to problems in forming wire from the alloy composite.

### EXAMPLES

Examples which follow are illustrative of highly conductive base metal alloy composites within the scope of the present invention.

In the first group of examples, rods of 250 microns were produced from gold alloy ingots (1.5 cm diameter) by swaging at room temperature and were then converted into gold alloy wire having a diameter of 25 microns by drawing. The swaging operation was conducted at room temperature and involved a per pass reduction of 15% in cross-sectional area in a two-hammer rotary mill to a diameter of 250 microns. The drawing operation involved a series of dies with a nominal 8%-15% reduction per die and included lubrication using an immersion bath with a mineral oil or water-based lubricant.

Each of the aforementioned rods that was converted into wire was prepared from an ingot comprising a gold alloy mixture that contained gold and the alloying constituent that is identified in Table 1 below. Each of the ingots that was formed into the rod was prepared by either a melt processing technique or by a powder metallurgy technique, as indicated in Table 1. The melt processing technique involved co-melting by non-consumable arc casting, or crucible melting followed by chill casting. The powder metallurgy technique involved: mixing of powder of less than about 100 microns; and cold isostatic pressing at 200 Mpa, followed by hot isostatic pressing at 200 Mpa and 700° C. It is noted that some of the exemplary wires that are described in Table 1 below comprise more than one sample of wire in that different methods of preparation were used in preparing the gold-based ingots from which the wire samples were formed, as indicated in Table 1 (see Example Nos. 1, 4, 10, 11 and 12). Table 2 below includes a report of the properties of some of the exemplary wires identified in Table 1. Those wires that were formed from gold-based ingots that were made by different methods have the same properties. This accounts for the report in Table 2 of but one value for each of the tensile strength and tensile elongation properties.

The alloying constituent(s) of the gold alloy composites that were prepared and the amounts thereof are identified in Table 1. The balance of each of the composites comprises gold which had a purity of 99.99 wt. %.

TABLE 1

| Ex. | Alloying | Amount of Alloying | Method of Preparation |
|---|---|---|---|
| No. | Constituent | Constituent, Vol. % | of Gold-Based Ingot |
| 1 | molybdenum | 10 | crucible melting/chill |
| | | | casting; non-consumable |
| | | | arc casting; powder |
| | | | metallurgy |
| 2 | rhodium | 10 | non-consumable arc casting |
| 3 | rhenium | 10 | non-consumable arc casting |
| 4 | iridium | 10 | crucible melting/chill |
| | | | casting; non-consumable |
| | | | arc casting; powder |
| | | | metallurgy |
| 5 | cobalt | 10 | non-consumable arc casting |
| 6 | platinum | 10 | non-consumable arc casting |
| 7 | platinum | 5 | non-consumable arc casting |
| 8 | nickel | 10 | non-consumable arc casting |
| 9 | nickel | 5 | non-consumable arc |
| | | | casting; crucible |
| | | | melting/chill casting |
| 10 | nickel | 5 | non-consumable arc |
| | and silicon | 0.5 | casting; crucible |
| | | | melting/chill casting |
| 11 | nickel | 5 | non-consumable arc |
| | and silicon | 0.1 | casting; crucible |
| | | | melting/chill casting |
| 12 | nickel | 5 | non-consumable arc |
| | and silicon | 1 | casting; crucible |
| | | | melting/chill casting |

The properties of various of the gold alloy composites identified in Table 1 above were evaluated. The properties of conventional alloys of the type used in electrical inter-connectors were evaluated also for comparative purposes (alloy C-1). The evaluations included, as indicated in Table 2, data for “Hard as Drawn” (HAD) and “Annealed” (On-Line Continuous at 500° C.).

TABLE 2

| | Ultimate Tensile | Tensile |
|---|---|---|
| Alloy | Strength, Mpa | Elongation, % |
| C-1, gold & 7 ppm | 400 | 2.0 |
| Be & 20 ppm Ca (HAD) | | |
| C-1, gold & 7 ppm | 250 | 4.0 |
| Be & 20 ppm Ca | | |
| (Annealed) | | |
| Ex1, gold & 10% molybdenum | 600 | 2.4 |
| Ex9, gold & 5% nickel (HAD) | 756 | 1.6 |
| Ex9, gold & 5% nickel | 497 | 7.6 |
| (Annealed) | | |
| Ex12, gold, 5% nickel, & | 823 | 2.3 |
| 1% Si (HAD) | | |
| Ex12, gold, 5% nickel, | 576 | 2.3 |
| & 1% Si (Annealed) | | |

The data in Table 2 show clearly the improved strengths of the gold alloy composites of the present invention relative to those of the prior art alloys which consist of gold alloy solutions. The improvements in strength are significant in both the HAD and Annealed evaluations. With reference to tensile ductility, the ability to maintain limited ductility in the alloys is mandatory for a wire-bonding process. However, ductility should be greater than 0.5% to prevent wire failure in its ultimate use. Table 2 shows that alloys of the present invention have improved strength and acceptable tensile ductility.

In a second group of examples, rods of 250 microns are produced from copper alloy ingots (5 cm diameter) by swaging at room temperature and are then converted into copper alloy wire having a diameter of 25 microns by drawing. The swaging operation is conducted at room temperature and involves a per pass reduction of 15% in cross-sectional area in a two-hammer rotary mill to a diameter of 250 microns. The drawing operation involved a series of dies with a nominal 8%-15% reduction per die and included lubrication using an immersion bath with a mineral oil or water-based lubricant.

Each of the aforementioned rods that is converted into wire is prepared from an ingot comprising a copper alloy mixture that contains copper and the alloying constituent that is identified in Table 3 below. Each of the ingots that is formed into the rod is prepared by either a melt processing technique or by a powder metallurgy technique, as indicated in Table 3. The melt processing technique involves co-melting by non-consumable arc casting or crucible melting followed by chill casting or consumable arc melting. The powder metallurgy technique involves: mixing of powder of less than about 100 microns; and cold isostatic pressing at 250 Mpa, followed by hot isostatic pressing at 250 Mpa and 900° C. It is noted that some of the exemplary wires that are described in Table 3 below comprise more than one sample of wire in that different methods of preparation are used in preparing the copper-based ingots from which the wire samples are formed, as indicated in Table 3.

The alloying constituent(s) of the copper alloy composites that are prepared and the amounts thereof are identified in Table 3. The balance of each of the composites comprises copper having a purity of 99.9 wt. %.

TABLE 3

| Ex. | Alloying | Amount of Alloying | Method of Preparation |
|---|---|---|---|
| No. | Constituent | Constituent, Vol. % | of Copper-Based Ingot |
| 13 | niobium | 3 | crucible melting/chill |
| | | | casting; non-consumable |
| | | | arc casting; powder |
| | | | metallurgy |
| 14 | niobium | 7.5 | crucible melting/chill |
| | | | casting; non-consumable |
| | | | arc casting; powder |
| | | | metallurgy |
| 15 | niobium | 15 | crucible melting/chill |
| | | | casting; non-consumable |
| | | | arc casting; powder |
| | | | metallurgy |
| 16 | chromium | 3 | crucible melting/chill |
| | | | casting |
| 17 | chromium | 5 | crucible melting/chill |
| | | | casting |
| 18 | chromium | 10 | crucible melting/chill |
| | | | casting |
| 19 | tantalum | 5 | consumable arc melting |
| 20 | vanadium | 5 | consumable arc melting |

The properties of various of the copper alloy composites identified in Table 3 above were evaluated. The evaluations included, as indicated in Table 4 below, data for “Hard as Drawn” (HAD) and “Annealed” (On-Line Continuous at 500° C.).

TABLE 4

| | | Ultimate Tensile | Tensile |
|---|---|---|---|
| Alloy | | Strength, Mpa | Elongation, % |
| Ex. 13 | Cu & 3% Nb | | |
| | Annealed | 275 | 4.0 |
| | HAD | 325 | 3.0 |
| Ex. 14 | Cu & 7.5% Nb | | |
| | Annealed | 315 | 4.0 |
| | HAD | 485 | 2.5 |
| Ex. 15 | Cu & 15% Nb | | |
| | Annealed | 405 | 2.0 |
| | HAD | 900 | 1.0 |
| Ex. 16 | Cu & 3% Cr | | |
| | Annealed | 310 | 3.0 |
| | HAD | 435 | 1.5 |
| Ex. 17 | Cu & 5% Cr | | |
| | Annealed | 320 | 3.0 |
| | HAD | 445 | 1.5 |
| Ex. 18 | Cu & 10% Cr | | |
| | Annealed | 400 | 2.6 |
| | HAD | 515 | 1.1 |
| Ex. 19 | Cu & 5% Ta | | |
| | Annealed | 324 | 3.3 |
| | HAD | 466 | 2.7 |
| Ex. 20 | Cu & 5% V | | |
| | Annealed | 297 | 3.8 |
| | HAD | 344 | 2.9 |

Evaluations show that the properties of alloys of Table 4 above are better relative to those of the copper base metal. Evaluations show also the corrosion-resistant properties of alloys which include alloying constituents like chromium, niobium, and tantalum are better than those of the copper base metal.

It should be appreciated that the present invention provides improved means for improving the properties of highly conductive metals in an economical and practical manner and that thin wires which are formed from the alloy composite of the present invention can be put to excellent use in various applications, including particularly semiconductor applications.

1. A metal alloy composite comprising a phase of gold in the form of a matrix and a phase of another metal positioned within the matrix, the gold being present in a major amount and the other metal being present in a minor amount.

2. A composite according to claim 1 wherein the other metal is in the form of particles.

3. A composite according to claim 2 wherein the particles are in elongated form.

4. A composite according to claim 1 in the form of a wire.

5. A composite according to claim 4 in the form of a wire which includes a plurality of parallel, axially aligned fibers of the other metal.

6. A composite according to claim 4 wherein the wire has a diameter of no greater than about 50 microns, a tensile strength of at least about 300 Mpa and a tensile elongation of at least about 1%.

7. A composite according to claim 6 wherein the wire has a diameter of about 10 to about 40 microns, a strength of about 300 to about 1000 Mpa, and a tensile elongation of about 1 to about 15%.

8. A composite according to claim 7 wherein the wire has a diameter of about 15 to about 30 microns, a strength of about 500 to about 1000 Mpa, and a tensile elongation of about 2 to about 8%.

9. A process for preparing a gold alloy wire comprising:
(A) providing a solid composition comprising a phase of gold in the form of a matrix and a phase of another metal positioned within the matrix, the gold being present in the composition in a major amount and the other metal in a minor amount; and
(B) subjecting the composition to deformation processing under conditions which shape the composition into the form of a wire which includes a plurality of parallel axially aligned fibers of the other metal.

10. A process for preparing a gold alloy composite comprising:
(A) forming a mixture containing a major amount of molten gold and a minor amount of another metal, the other metal being molten and immiscible with the molten gold or being solid and insoluble in the molten gold;
(B) cooling the mixture under conditions which are effective in forming a solid gold alloy composite comprising a phase of gold in the form of a matrix and a phase of the other metal positioned in the matrix.

11. A terminal assembly comprising an electrically conductive terminal in conductive contact with a conductive member and another electrically conductive terminal in conductive contact with a semiconductor, said terminals being joined by a wire comprising a metal alloy composite comprising a phase of a highly conductive base metal in the form of a matrix and a base phase of another metal positioned within the matrix, the base metal being present in a major amount and the other metal being present in a minor amount.

12. An assembly according to claim 11 wherein the alloy composite comprises a major amount of copper.

13. An assembly according to claim 12 wherein said wire has a diameter of no greater than about 50 microns, a tensile strength of at least about 300 Mpa, and a tensile elongation of at least about 1%.

14. An assembly according to claim 12 wherein the wire has a diameter of about 10 to about 40 microns, a strength of about 300 to about 1000 Mpa, and a tensile elongation of about 1 to about 15%.

15. An assembly according to claim 12 wherein the wire has a diameter of about 15 to about 30 microns, a strength of about 500 to about 1000 Mpa, and a tensile elongation of about 2 to about 8%.

16. An assembly according to claim 11 wherein the alloy composite comprises a major amount of copper and a minor amount of niobium.

17. An assembly according to claim 11 wherein the alloy composite comprises a major amount of copper and a minor amount of chromium.

18. An assembly according to claim 11 wherein the alloy composite comprises a major amount of copper and a minor amount of tantalum.

19. An assembly according to claim 11 wherein the alloy composite comprises a major amount of copper and a minor amount of vanadium.

20. An alloy composite according to claim 1 including a minor amount of iridium.

21. An alloy composite according to claim 1 including a minor amount of rhodium.

22. An alloy composite according to claim 1 including a minor amount of molybdenum.

23. An alloy composite according to claim 1 including a minor amount of each of iron and molybdenum.

24. An alloy composite according to claim 1 including a minor amount of each of nickel and niobium.

25. An alloy composite according to claim 1 including a minor amount of each of iron and silicon.

26. An assembly according to claim 11 wherein the alloy composite comprises a major amount of gold.

27. An assembly according to claim 11 wherein the alloy composite comprises a major amount of aluminum.
